(19) United States
(12) Patent Application Publication
(10) Pub. No.: US 2026/0237447 A1
(43) Pub. Date: Aug. 13, 2026

(54) MEMORY DEVICES AND METHODS OF MANUFACTURING THEREOF

(71) Applicant: Taiwan Semiconductor Manufacturing Company, Ltd., Hsinchu (TW)

(72) Inventors: Ryota Watanabe, Hsinchu City (TW); Kazumasa Uno, Hsinchu City (TW); Hidemitsu Kojima, Hsinchu City (TW); Hiromasa Otsubo, Hsinchu City (TW); Tai-Te Chu, Hsinchu City (TW)

(73) Assignee: Taiwan Semiconductor Manufacturing Company, Ltd., Hsinchu (TW)

(21) Appl. No.: 19/049,330

(22) Filed: Feb. 10, 2025

(51) Int. Cl. G11C 17/12; H10B 20/00

(52) U.S. Cl. CPC G11C 17/126; H10B 20/387

(57) ABSTRACT

A circuit includes memory cells, each from one of first, second, third, or fourth cells. The first cell includes a transistor having a gate coupled to a first wordline, a first source/drain coupled to a first interconnect carrying a ground voltage, and a second source/drain coupled to the first interconnect. The second cell includes a transistor having a gate coupled to a second wordline, a first source/drain coupled to a second interconnect configured as a bitline, and a second source/drain coupled to the second interconnect. The third cell includes a transistor having a gate coupled to a third wordline, a first source/drain coupled to the first interconnect, and a second source/drain coupled to the second interconnect. The fourth cell includes a transistor having a gate coupled to a fourth wordline, a first source/drain coupled to the second interconnect, and a second source/drain coupled to the first interconnect.

### BACKGROUND

The semiconductor integrated circuit (IC) industry has experienced exponential growth. As ICs continue to scale down, more devices are integrated into the single chip. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example memory device (or circuit), in accordance with some embodiments.

FIG. 2 illustrates a circuit diagram of an example memory array that can be included in the memory device of FIG. 1, in accordance with some embodiments.

FIG. 3 illustrates schematic and layout views of an example memory array that can be included in the memory device of FIG. 1, in accordance with some embodiments.

FIG. 4 illustrates a circuit diagram of an example memory array that can be included in the memory device 100 of FIG. 1, in accordance with some embodiments.

FIG. 5 illustrates schematic and layout views of an example memory array that can be included in the memory device of FIG. 1, in accordance with some embodiments.

FIG. 6 illustrates a block diagram of an example memory device (or circuit), in accordance with some embodiments.

FIGS. 7A and 7B illustrate schematic diagrams of an example memory array, in accordance with some embodiments.

FIG. 8 illustrates a block diagram of an example memory device (or circuit), in accordance with some embodiments.

FIG. 9 is a flow chart of an example method for programming a memory circuit, in accordance with some embodiments.

FIG. 10 is a flow chart of an example method for programming a memory circuit, in accordance with some embodiments.

FIG. 11 is a flow chart of an example method for programming a memory circuit, in accordance with some embodiments.

FIG. 12 is a flow chart of an example method for programming a memory circuit, in accordance with some embodiments.

FIG. 13 is a flow chart of an example method for programming a memory circuit, in accordance with some embodiments.

FIG. 14 is a flow chart of an example method that can be performed as part of the method of FIG. 13, in accordance with some embodiments.

FIG. 15 is a flow chart of an example method that can be performed as part of the method of FIG. 13, in accordance with some embodiments.

FIG. 16 is a flow chart of an example method that can be performed as part of the method of FIG. 13, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In advanced memory technologies, binary data can be embedded into memory cell layouts, where each binary bit corresponds to a specific memory cell. To improve the layout and functionality, isolation dummy cells are often inserted between subarrays of memory cells. While this approach simplifies the conversion process and helps manage variations, it introduces significant area overhead, increasing the overall footprint of the memory design. The isolation dummy cells may be eliminated to reduce the area overhead but creates challenges related to layout redundancy. For example, the expanded design phase space leads to variations in characteristics like cell stability, bit-line load, and read margins, thereby sacrificing efficiency in finding a mapped column for the memory circuit.

The present disclosure provides techniques for efficient conversion methods. By eliminating isolation dummy cells and embedding the original data using only a certain number of memory cells, the area overhead can be reduced while maintaining consistent performance. This can thereby allow binary data to be embedded into memory cell layouts with improved efficiency and minimized variation. Efficient conversion methods disclosed herein can streamline the process of generating schematics and layouts, significantly reducing design time. Furthermore, the introduction of an additional sign column and a method for generating sign bits effectively suppresses bit-line load variations, ensuring enhanced stability and reliability across the memory array.

According to the present disclosure, in some embodiments, a memory circuit includes a memory array including a plurality of memory cells, each of the memory cells selected from one of a first memory cell, a second memory cell, a third memory cell, or a fourth memory cell. The first memory cell includes a first transistor having a gate terminal coupled to a first word line, a first source/drain terminal coupled to a first interconnect structure carrying a ground voltage, and a second source/drain terminal coupled to the first interconnect structure. The second memory cell includes a second transistor having a gate terminal coupled to a second word line, a first source/drain terminal coupled to a second interconnect structure configured as a bit line, and a second source/drain terminal coupled to the second interconnect structure. The third memory cell includes a third transistor having a gate terminal coupled to a third word line, a first source/drain terminal coupled to the first interconnect structure, and a second source/drain terminal coupled to the second interconnect structure. The fourth memory cell includes a fourth transistor having a gate terminal coupled to a fourth word line, a first source/drain terminal coupled to the second interconnect structure, and a second source/drain terminal coupled to the first interconnect structure.

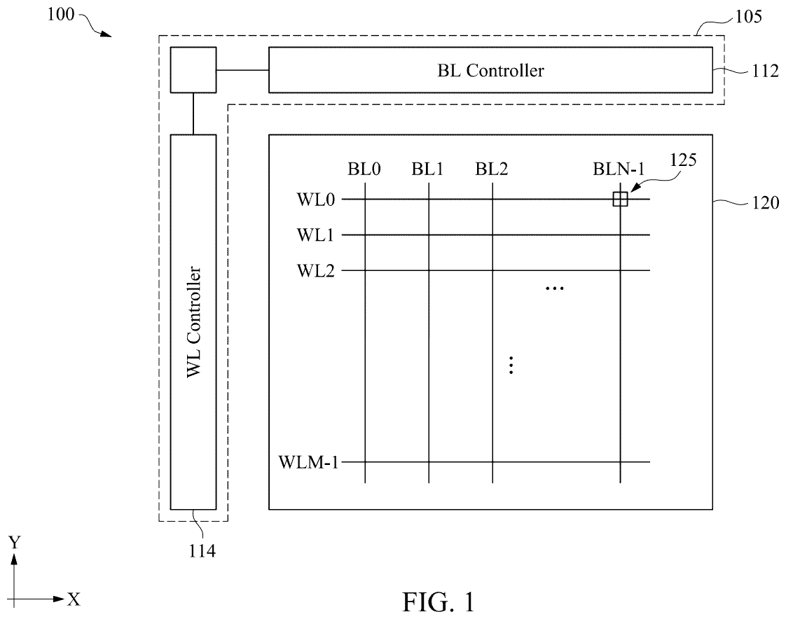

FIG. 1 illustrates a block diagram of an example memory device (or circuit) 100, in accordance with some embodiments. The memory device 100 includes a memory controller 105 and a memory array 120. In one aspect, the memory array 120 includes a plurality of storage circuits or memory cells 125. The memory array 120 includes word lines WL₀, WL₁ . . . WL_{M-1}, each extending in a direction (e.g., X-direction) and bit lines BL₀, BL₁ . . . BL_{N-1}, each extending in another direction (e.g., Y-direction). The word lines WLs and the bit lines BLs may each be a conductive metal or conductive rail. In some embodiments, each memory cell 125 is coupled to a corresponding word line WL and a corresponding bit line BL, and can be operated according to voltages or currents through the corresponding word line WL and the corresponding bit line BL. In some embodiments, each bit line includes bit lines BL, BLB coupled to one or more memory cells 125 of a group of memory cells 125 disposed along the direction (e.g., Y-direction). The bit lines BL, BLB may receive and/or provide differential signals.

Each memory cell 125 may include a volatile memory cell, a non-volatile memory cell, or a combination of them. For example, each memory cell 125 is embodied as a static random access memory (SRAM) cell, etc. However, it should be appreciated that the memory cell 125 can be implemented as any of various other non-volatile memory cells such as, for example, a resistive random access memory (RRAM) cell, a magnetoresistive random access memory (MRAM) cell, a phase-change random access memory (PCRAM) cell, an eFuse, an anti-fuse, a Read-Only Memory (ROM) (e.g., a ROM compiler), etc., while remaining within the scope of the present disclosure. For example, each of the memory cells 125 may include a ROM cell.

The memory controller 105 is a hardware component that controls operations of the memory array 120. In some embodiments, the memory controller 105 includes a bit line (BL) controller 112, a word line (WL) controller 114, etc. The BL controller 112 and the WL controller 114 may be embodied as logic circuits, analog circuits, or a combination of them. In one configuration, the WL controller 114 can be a circuit that provides a voltage or current through one or more word lines WLs of the memory array 120. The BL controller 112 can be a circuit that provides or senses a voltage or current through one or more bit lines BLs of the memory array 120. The BL controller 112 may be coupled to bit lines BLs of the memory array 120, and the WL controller 114 may be coupled to word lines WLs of the memory array 120.

In some embodiments, the memory array 120 includes a plurality of memory cells (e.g., the memory cell 125), each of which is selected from one of a first memory cell, a second memory cell, a third memory cell, or a fourth memory cell. The first memory cell includes a first transistor having a gate terminal coupled to a first word line, a first source/drain terminal coupled to a first interconnect structure carrying a ground voltage, and a second source/drain terminal coupled to the first interconnect structure. The second memory cell includes a second transistor having a gate terminal coupled to a second word line, a first source/drain terminal coupled to a second interconnect structure configured as a bit line, and a second source/drain terminal coupled to the second interconnect structure. The third memory cell includes a third transistor having a gate terminal coupled to a third word line, a first source/drain terminal coupled to the first interconnect structure, and a second source/drain terminal coupled to the second interconnect structure. The fourth memory cell includes a fourth transistor having a gate terminal coupled to a fourth word line, a first source/drain terminal coupled to the second interconnect structure, and a second source/drain terminal coupled to the first interconnect structure.

In some embodiments, the memory array 120 includes a plurality of memory cells (e.g., the memory cell 125) arranged over a plurality of word lines extending along a first lateral direction, a plurality of reference lines extending along a second lateral direction perpendicular to the first lateral direction, and a plurality of signal lines (e.g., bit lines, data lines, etc.) extending along the second lateral direction. Each of the memory cells is selected from one of a first memory cell, a second memory cell, a third memory cell, or a fourth memory cell. The first memory cell includes its first and second source/drain terminals both connected to a corresponding one of the plurality of reference lines. The second memory cell includes its first and second source/drain terminals both connected to a corresponding one of the plurality of signal lines (e.g., bit lines, data lines, etc.). The third memory cell includes its first and second source/drain terminals connected to a corresponding one of the plurality of signal lines (e.g., bit lines, data lines, etc.) and a corresponding one of the plurality of reference lines, respectively. The fourth memory cell includes its first and second source/drain terminals connected to a corresponding one of the plurality of reference lines and a corresponding one of the plurality of signal lines (e.g., bit lines, data lines, etc.), respectively.

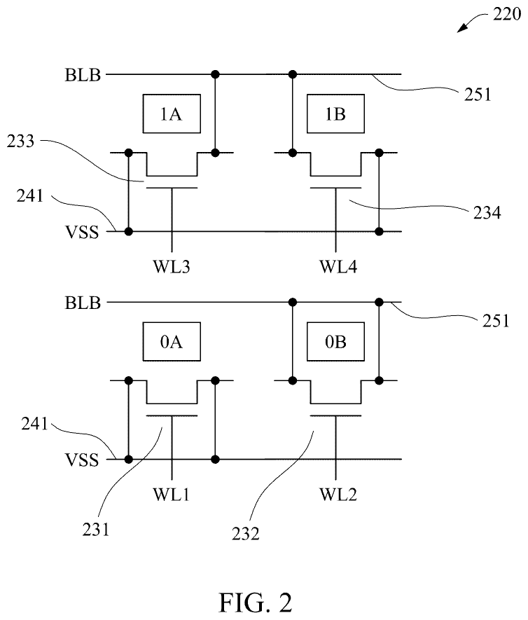

FIG. 2 illustrates a circuit diagram of an example memory array 220 that can be included in the memory device 100 of FIG. 1, in accordance with some embodiments. In some embodiments, the memory array 220 may be substantially similar to or incorporate features of the memory array 120. It should be appreciated that the memory array 220 of FIG. 2 is simplified for illustrative purposes, and thus, the memory array 220 can be implemented as any of various other configurations while remaining within the scope of the present disclosure.

The memory array 220 includes a first memory cell 0A, a second memory cell 0B, a third memory cell 1A, and a fourth memory cell 1B. In some embodiments, each of the memory cells in the memory array 220 can be selected from one of the first memory cell 0A, the second memory cell 0B, the third memory cell 1A, or the fourth memory cell 1B. In some embodiments, the first memory cell 0A includes a first transistor 231. The first transistor 231 can have a gate terminal coupled to a first word line WL1, a first source/drain terminal coupled to a first interconnect structure 241 carrying a ground voltage VSS, and a second source/drain terminal coupled to the first interconnect structure 241. In some embodiments, the second memory cell 0B includes a second transistor 232. The second transistor 232 can have a gate terminal coupled to a second word line WL2, a first source/drain terminal coupled to a second interconnect structure 251 configured as a bit line, and a second source/drain terminal coupled to the second interconnect structure 251. In some embodiments, the third memory cell 1A includes a third transistor 233. The third transistor 233 can have a gate terminal coupled to a third word line WL3, a first source/drain terminal coupled to the first interconnect structure 241, and a second source/drain terminal coupled to the second interconnect structure 251. In some embodiments, the fourth memory cell 1B includes a fourth transistor 234. The fourth transistor 234 can have a gate terminal coupled to a fourth word line WL4, a first source/drain terminal coupled to the second interconnect structure 251, and a second source/drain terminal coupled to the first interconnect structure 241. In some embodiments, the first memory cell 0A and the second memory cell 0B can operatively correspond to a first logic state (e.g., “1”), and the third memory cell 1A and the fourth memory cell 1B can operatively correspond to a second logic state (e.g., “0”). In some embodiments, at least one of the first transistor 231, the second transistor 232, the third transistor 233, and the fourth transistor 234 can be an NMOS transistor. For example, each of the first transistor 231, the second transistor 232, the third transistor 233, and the fourth transistor 234 can be an NMOS transistor.

In some embodiments, the first interconnect structure 241 may be a reference line. In some embodiments, the second interconnect structure 251 may be a signal line (e.g., a bit line, a data line, etc.). In some embodiments, the memory cells of the memory array 220 may be arranged over a plurality of word lines (e.g., the word lines WL1, WL2, WL3, WL4, etc.) extending along a first lateral direction, a plurality of reference lines (e.g., the first interconnect structure 241) extending along a second lateral direction perpendicular to the first lateral direction, and a plurality of signal lines (e.g., the second interconnect structure 251, bit lines, data lines, etc.) extending along the second lateral direction. In some embodiments, the word lines WL1, WL2, WL3, WL4 may physically extend in the first lateral direction, and the first and second interconnect structures 241, 251 may extend in the second lateral direction perpendicular to the first lateral direction.

In some embodiments, the first memory cell 0A can have its first and second source/drain terminals both connected to a corresponding one of the plurality of reference lines (e.g., the first interconnect structure 241). The second memory cell 0B can have its first and second source/drain terminals both connected to a corresponding one of the plurality of signal lines (e.g., the second interconnect structure 251, bit lines, data lines, etc.). The third memory cell 1A can have its first and second source/drain terminals connected to a corresponding one of the plurality of signal lines (e.g., the second interconnect structure 251, bit lines, data lines, etc.) and a corresponding one of the plurality of reference lines (e.g., the first interconnect structure 241), respectively. The fourth memory cell 1B can have its first and second source/drain terminals connected to a corresponding one of the plurality of reference lines (e.g., the first interconnect structure 241) and a corresponding one of the plurality of signal lines (e.g., the second interconnect structure 251, bit lines, data lines, etc.), respectively.

As disclosed herein, by embedding data using a predetermined number of memory cells (e.g., four cells as shown in FIG. 2), the memory array 220 allows for reduced overhead area while maintaining consistent performance and reliability, as discussed in greater detail below. For example, a column of original data, d^{m}=[d₀, . . . , d_{N-1}] where dᵢ∈{1, 0} (2^{N} combinations), can be coded into a mapped column with the memory array 220, c^{m}=[c₀, . . . , c_{N-1}] where cᵢ∈{1A, 1B, 0A, 0B} (2^{N+1} combinations). In some embodiments, except for the factor of 2, the number of the possible combinations for the memory array (2^{N+1} combinations) matches the number of the possible combinations for the original data (2^{N} combinations). This can narrow down the phase spaces for the memory array and reduces resources (e.g., time, computation, etc.) to find c^{m} can be reduced for any given original data d. Additionally, minimizing redundancy in the memory array herein reduces variation, which leads to improvements in timing specs, reliability, and yield.

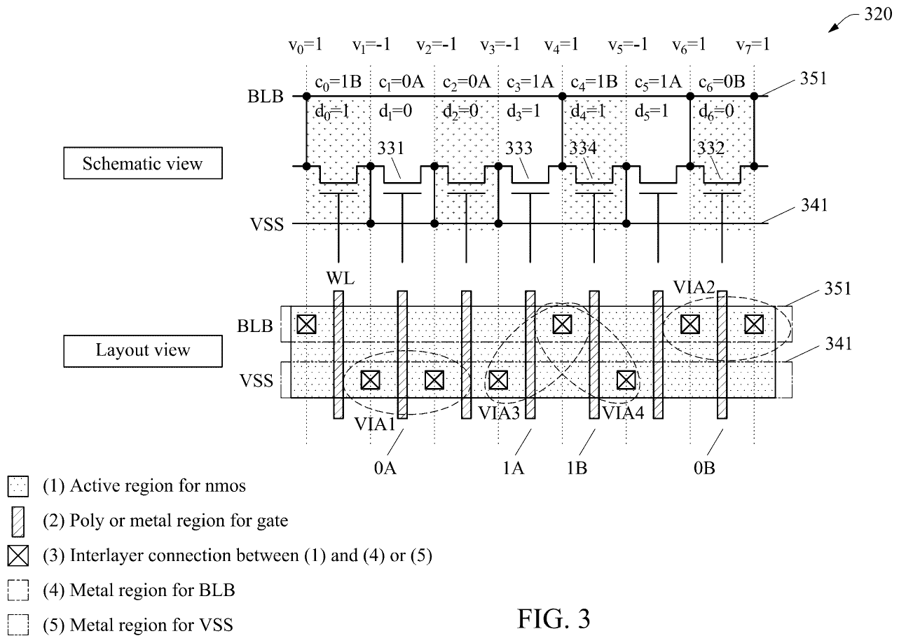

FIG. 3 illustrates schematic and layout views of an example memory array 320 that can be included in the memory device 100 of FIG. 1, in accordance with some embodiments. Specifically, shown in the memory array 320, in which a column of original data, d^{m}=[d₀, . . . , d_{N-1}] (m=0, . . . , M−1; M is a number of columns for the original data matrix), can be embedded into a ROM cell chain c^{m} (which can be equivalently referred to as a via array v^{m}=[v₀, . . . , V_{N}] where vᵢ∈{−1(on VSS), 1(on BLB)}). In some embodiments, the memory array 320 may be substantially similar to or incorporate features of the memory array 220. It should be appreciated that the schematic and layout views shown in FIG. 3 are simplified for illustrative purposes, and thus, can be implemented as any of various other configurations while remaining within the scope of the present disclosure.

Referring to the schematic and layout views, the memory array 320 can include a plurality of via structures. In some embodiments, the memory array 320 includes a pair of first via structures VIA1 connecting first and second source/drain terminals of a first transistor 331 to a first interconnect structure 341 (e.g., VSS). In some embodiments, the memory array 320 includes a pair of second via structures VIA2 connecting first and second source/drain terminals of a second transistor 332 to a second interconnect structure 351 (e.g., BLB). In some embodiments, the memory array 320 includes a pair of third via structures VIA3 connecting first and second source/drain terminals of a third transistor 333 to the first interconnect structure 341 and the second interconnect structure 351, respectively. In some embodiments, the memory array 320 includes a pair of fourth via structures VIA4 connecting first and second source/drain terminals of a fourth transistor 334 to the second interconnect structure 351 and the first interconnect structure 341, respectively.

Memory cells of the memory array disclosed herein can be selected, arranged, or configured based on a first type of memory cell (e.g., the first memory cell 0A), a second type of memory cell (e.g., the second memory cell 0B), a third type of memory cell (e.g., the third memory cell 1A), or a fourth type of memory cell (e.g., the fourth memory cell 1B).

In some embodiments, a plurality of memory cells of the memory array 320 can be physically arranged along a lateral direction, with an initial one of the plurality of memory cells being a first memory cell 0A and an immediately next one (e.g., one of the neighboring cells in a processing direction; e.g., a neighboring cell on the right-hand side of FIG. 3) of the plurality of memory cells being a first memory cell 0A or a third memory cell 1A. In some embodiments, a plurality of memory cells of the memory array 320 can be physically arranged along a lateral direction, with an initial one of the plurality of memory cells being a second memory cell 0B and an immediately next one of the plurality of memory cells being a second memory cell 0B or a fourth memory cell 1B. In some embodiments, a plurality of memory cells of the memory array 320 can be physically arranged along a lateral direction, with an initial one of the plurality of memory cells being a third memory cell 1A and an immediately next one of the plurality of memory cells being a second memory cell 0B or a fourth memory cell 1B. In some embodiments, a plurality of memory cells of the memory array 320 can be physically arranged along a lateral direction, with an initial one of the plurality of memory cells being a fourth memory cell 1B and an immediately next one of the plurality of memory cells being a first memory cell 0A or a third memory cell 1A.

In Table 1, shown is an example relationship between each data, d₀, . . . , d_{N-1}, an initial cell (cₙ₋₁), and an immediately next cell (cₙ).

TABLE 1

| cₙ₋₁ | dₙ | cₙ |
|---|---|---|
| 0A | 0 | 0A |
| | 1 | 1A |
| 0B | 0 | 0B |
| | 1 | 1B |
| 1A | 0 | 0B |
| | 1 | 1B |
| 1B | 0 | 0A |
| | 1 | 1A |

Referring to FIG. 3, an initial cell (c₀) can be a fourth cell 1B, and d₀=1 is provided. Based on Table 1, with the fourth cell 1B (c₀) as an initial cell, a next cell (c₁) can be a first cell 0A for d₁=0. Similarly, with the first cell 0A (c₁) as an initial cell, a next cell (c₂) can be a first cell 0A for d₂=0. With the first cell 0A (c₂) as an initial cell, a next cell (c₃) can be a third cell 1A for d₃=1. With the third cell 1A (c₃) as an initial cell, a next cell (c₄) can be a fourth cell 1B for d₄=1. With the fourth cell 1B (c₄) as an initial cell, a next cell (c₅) can be a third cell 1A for d₅=1. With the third cell 1A (c₅) as an initial cell, a next cell (c₆) can be a second cell 0B for d₆=0.

In some embodiments, a number of the plurality of memory cells can be equal to N, and a number of the first via structures VIA1 or a number of the second via structures VIA2 can be equal to or less than N/2. For example, a number of arranged (or selected) memory cells in the memory array can be equal to N, and a number of connections on the first interconnect structure 341 or the second interconnect structure 351 can be equal to or less than N/2. As a non-limiting example, in FIG. 3, four connections are formed on the first interconnect structure 341 with the number of arranged (or selected) memory cells being seven; four connections are formed on the second interconnect structure 351 with the number of arranged (or selected) memory cells being seven.

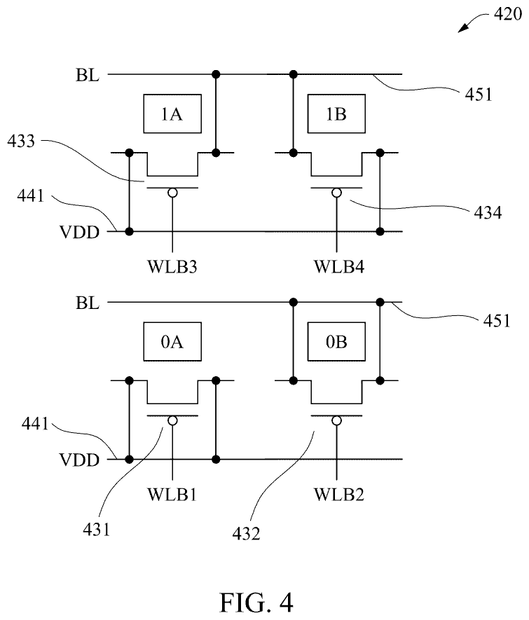

FIG. 4 illustrates a circuit diagram of an example memory array 420 that can be included in the memory device 100 of FIG. 1, in accordance with some embodiments. In some embodiments, the memory array 420 may be substantially similar to or incorporate features of the memory array 120. It should be appreciated that the memory array 420 of FIG. 4 is simplified for illustrative purposes, and thus, the memory array 420 can be implemented as any of various other configurations while remaining within the scope of the present disclosure.

The memory array 420 includes a first memory cell 0A, a second memory cell 0B, a third memory cell 1A, and a fourth memory cell 1B. In some embodiments, each of the memory cells in the memory array 420 can be selected from one of the first memory cell 0A, the second memory cell 0B, the third memory cell 1A, or the fourth memory cell 1B. In some embodiments, the first memory cell 0A includes a first transistor 431. The first transistor 231 can have a gate terminal coupled to a first word line WLB1, a first source/drain terminal coupled to a first interconnect structure 441 carrying a supply voltage VDD, and a second source/drain terminal coupled to the first interconnect structure 441. In some embodiments, the second memory cell 0B includes a second transistor 432. The second transistor 432 can have a gate terminal coupled to a second word line WLB2, a first source/drain terminal coupled to a second interconnect structure 451 configured as a bit line, and a second source/drain terminal coupled to the second interconnect structure 451. In some embodiments, the third memory cell 1A includes a third transistor 433. The third transistor 433 can have a gate terminal coupled to a third word line WLB3, a first source/drain terminal coupled to the first interconnect structure 441, and a second source/drain terminal coupled to the second interconnect structure 451. In some embodiments, the fourth memory cell 1B includes a fourth transistor 434. The fourth transistor 434 can have a gate terminal coupled to a fourth word line WLB4, a first source/drain terminal coupled to the second interconnect structure 451, and a second source/drain terminal coupled to the first interconnect structure 441. In some embodiments, the first memory cell 0A and the second memory cell 0B can operatively correspond to a first logic state (e.g., “0”), and the third memory cell 1A and the fourth memory cell 1B can operatively correspond to a second logic state (e.g., “1”). In some embodiments, at least one of the first transistor 431, the second transistor 432, the third transistor 433, and the fourth transistor 434 can be a PMOS transistor. For example, each of the first transistor 431, the second transistor 432, the third transistor 433, and the fourth transistor 434 can be a PMOS transistor.

In some embodiments, the first interconnect structure 441 may be a reference line. In some embodiments, the second interconnect structure 451 may be a signal line (e.g., a bit line, a data line, etc.). In some embodiments, the memory cells of the memory array 420 may be arranged over a plurality of word lines (e.g., the word lines WLB1, WLB2, WLB3, WLB4, etc.) extending along a first lateral direction, a plurality of reference lines (e.g., the first interconnect structure 441) extending along a second lateral direction perpendicular to the first lateral direction, and a plurality of signal lines (e.g., the second interconnect structure 451, bit lines, data lines, etc.) extending along the second lateral direction. In some embodiments, the word lines WLB1, WLB2, WLB3, WLB4 may physically extend in the first lateral direction, and the first and second interconnect structures 441, 451 may extend in the second lateral direction perpendicular to the first lateral direction.

In some embodiments, the first memory cell 0A can have its first and second source/drain terminals both connected to a corresponding one of the plurality of reference lines (e.g., the first interconnect structure 441). The second memory cell 0B can have its first and second source/drain terminals both connected to a corresponding one of the plurality of signal lines (e.g., the second interconnect structure 451, bit lines, data lines, etc.). The third memory cell 1A can have its first and second source/drain terminals connected to a corresponding one of the plurality of signal lines (e.g., the second interconnect structure 451, bit lines, data lines, etc.) and a corresponding one of the plurality of reference lines (e.g., the first interconnect structure 441), respectively. The fourth memory cell 1B can have its first and second source/drain terminals connected to a corresponding one of the plurality of reference lines (e.g., the first interconnect structure 441) and a corresponding one of the plurality of signal lines (e.g., the second interconnect structure 451, bit lines, data lines, etc.), respectively.

As disclosed herein, by embedding data using a predetermined number of memory cells (e.g., four cells as shown in FIG. 4), the memory array 420 allows for reduced overhead area while maintaining consistent performance, as discussed in greater detail below. For example, a column of original data, d^{m}=[d₀, . . . , d_{N-1}] where dᵢ∈{1, 0} (2^{N} combinations), can be coded into a mapped column with the memory array 420, c^{m}=[c₀, . . . , c_{N-1}] where cᵢ∈{1A, 1B, 0A, 0B} (2^{N+1} combinations). In some embodiments, except for the factor of 2, the number of the possible combinations for the memory array (2^{N+1} combinations) matches the number of the possible combinations for the original data (2N combinations). This can narrow down the phase spaces for the memory array and reduces resources (e.g., time, computation, etc.) to find c^{m} can be reduced for any given original data d. Additionally, minimizing redundancy in the memory array herein reduces variation, which leads to improvements in timing specs, reliability, and yield.

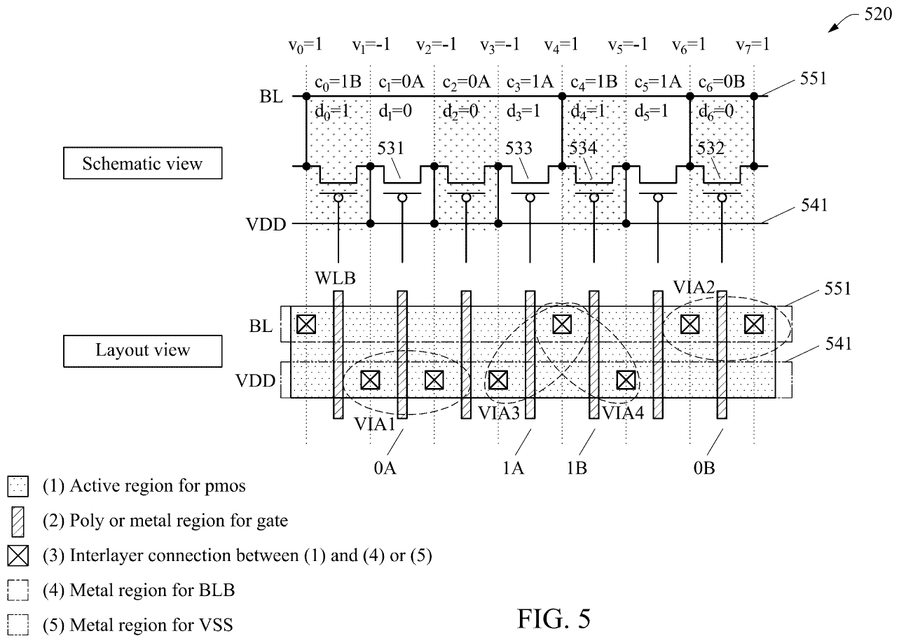

FIG. 5 illustrates schematic and layout views of an example memory array 520 that can be included in the memory device 100 of FIG. 1, in accordance with some embodiments. Specifically, shown in the memory array 520, in which a column of original data, d^{m}=[d₀, . . . , d_{N-1}] (m=0, . . . , M−1; M is a number of columns for the original data matrix), can be embedded into a ROM cell chain c^{m} (which can be equivalently referred to as a via array v^{m}=[v₀, . . . , v_{N}] where vᵢ∈{−1(on VDD), 1(on BL)}). In some embodiments, the memory array 520 may be substantially similar to or incorporate features of the memory array 420. It should be appreciated that the schematic and layout views shown in FIG. 5 are simplified for illustrative purposes, and thus, can be implemented as any of various other configurations while remaining within the scope of the present disclosure.

Referring to the schematic and layout views, the memory array 520 can include a plurality of via structures. In some embodiments, the memory array 520 includes a pair of first via structures VIA1 connecting first and second source/drain terminals of a first transistor 531 to a first interconnect structure 541 (e.g., VDD). In some embodiments, the memory array 520 includes a pair of second via structures VIA2 connecting first and second source/drain terminals of a second transistor 532 to a second interconnect structure 551 (e.g., BL). In some embodiments, the memory array 520 includes a pair of third via structures VIA3 connecting first and second source/drain terminals of a third transistor 533 to the first interconnect structure 541 and the second interconnect structure 551, respectively. In some embodiments, the memory array 520 includes a pair of fourth via structures VIA4 connecting first and second source/drain terminals of a fourth transistor 534 to the second interconnect structure 551 and the first interconnect structure 541, respectively.

Memory cells of the memory array disclosed herein can be selected, arranged, or configured based on a first type of memory cell (e.g., the first memory cell 0A), a second type of memory cell (e.g., the second memory cell 0B), a third type of memory cell (e.g., the third memory cell 1A), or a fourth type of memory cell (e.g., the fourth memory cell 1B).

In some embodiments, a plurality of memory cells of the memory array 520 can be physically arranged along a lateral direction, with an initial one of the plurality of memory cells being a first memory cell 0A and an immediately next one of the plurality of memory cells being a first memory cell 0A or a third memory cell 1A. In some embodiments, a plurality of memory cells of the memory array 520 can be physically arranged along a lateral direction, with an initial one of the plurality of memory cells being a second memory cell 0B and an immediately next one of the plurality of memory cells being a second memory cell 0B or a fourth memory cell 1B.

In some embodiments, a plurality of memory cells of the memory array 520 can be physically arranged along a lateral direction, with an initial one of the plurality of memory cells being a third memory cell 1A and an immediately next one of the plurality of memory cells being a second memory cell 0B or a fourth memory cell 1B. In some embodiments, a plurality of memory cells of the memory array 520 can be physically arranged along a lateral direction, with an initial one of the plurality of memory cells being a fourth memory cell 1B and an immediately next one of the plurality of memory cells being a first memory cell 0A or a third memory cell 1A.

Referring to FIG. 5, an initial cell (c₀) can be a fourth cell 1B, and d₀=1 is provided. Based on Table 1, with the fourth cell 1B (c₀) as an initial cell, a next cell (c₁) can be a first cell 0A for d₁=0. Similarly, with the first cell 0A (c₁) as an initial cell, a next cell (c₂) can be a first cell 0A for d₂=0. With the first cell 0A (c₂) as an initial cell, a next cell (c₃) can be a third cell 1A for d₃=1. With the third cell 1A (c₃) as an initial cell, a next cell (c₄) can be a fourth cell 1B for d₄=1. With the fourth cell 1B (c₄) as an initial cell, a next cell (c₅) can be a third cell 1A for d₅=1. With the third cell 1A (c₅) as an initial cell, a next cell (c₆) can be a second cell 0B for d₆=0.

In some embodiments, a number of the plurality of memory cells can be equal to N, and a number of the first via structures VIA1 or a number of the second via structures VIA2 can be equal to or less than N/2. For example, a number of arranged (or selected) memory cells in the memory array can be equal to N, and a number of connections on the first interconnect structure 541 or the second interconnect structure 551 can be equal to or less than N/2. As a non-limiting example, in FIG. 5, four connections are formed on the first interconnect structure 541 with the number of arranged (or selected) memory cells being seven; four connections are formed on the second interconnect structure 551 with the number of arranged (or selected) memory cells being seven.

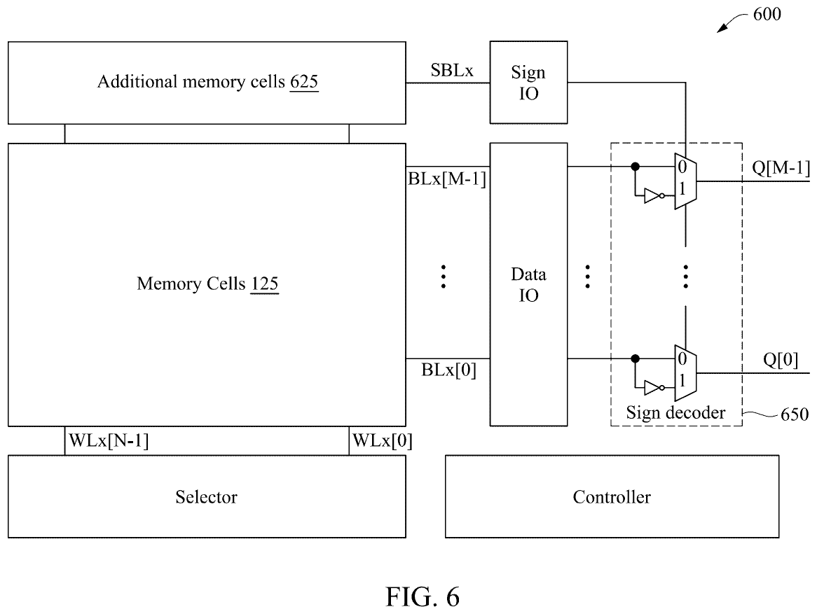

According to the present disclosure, in some embodiments, a memory circuit (e.g., the memory circuit 100) can include additional memory cells to reduce variation of BL load. FIG. 6 illustrates a block diagram of an example memory device (or circuit) 600, in accordance with some embodiments. In some embodiments, the memory device 600 may be substantially similar to or incorporate features of the memory device 100. The memory device 600 additionally includes additional memory cells 625 and a sign decoder 650, as opposed to the memory device 100. It should be appreciated that the memory device 600 shown in FIG. 6 is simplified for illustrative purposes, and thus, can be implemented as any of various other configurations while remaining within the scope of the present disclosure.

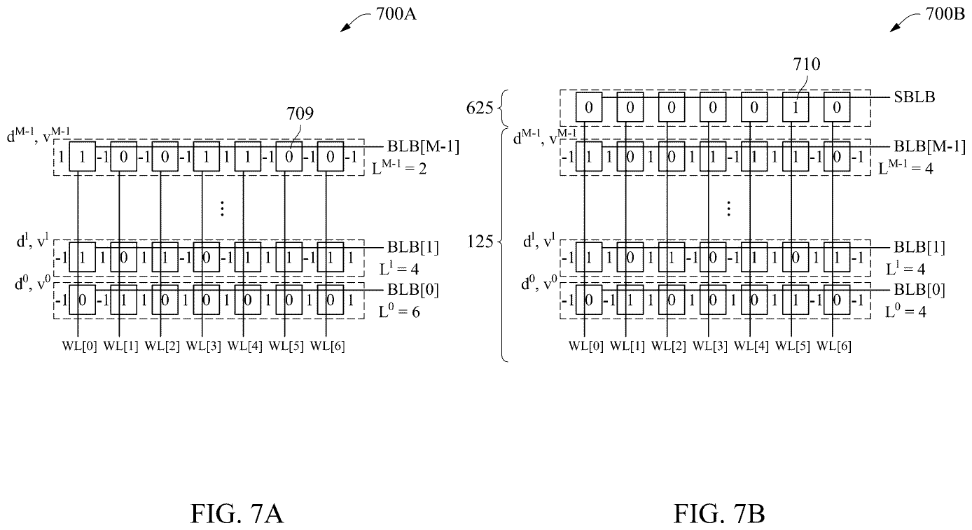

The memory cells 125 of the memory device 600 are arranged over a plurality of word lines extending along a first lateral direction, a plurality of reference lines extending along a second lateral direction perpendicular to the first lateral direction, and a plurality of signal lines (e.g., bit lines, data lines, etc.) extending along the second lateral direction. The additional memory cells 625 can extend along the second lateral direction. The additional memory cells 625 operatively corresponds to a sign of a corresponding subset of the memory cells 125 arranged along the first lateral direction. As discussed in greater detail below, the additional memory cells 625 can be configured as sign bit cells, which can suppress variation in BL loads of the memory cells. FIG. 7A illustrates a schematic diagram of an example memory array 700A, in accordance with some embodiments. In some embodiments, the memory array 700A may be substantially similar to or incorporate features of the memory array 120. It should be understood that the memory array 700A is shown for illustrative purposes, such as to show example original binary data (e.g., prior to attaching the additional memory cells 625 as shown in FIG. 7B). FIG. 7B illustrates a schematic diagram of an example memory array 700B, in accordance with some embodiments. In some embodiments, the memory array 700B may be substantially similar to or incorporate features of the memory array 120, 700A, etc. The memory array 700B includes the memory cells 125 and the additional memory cells 625, as opposed to the memory array 700A. It should be appreciated that the memory array 700B shown in FIG. 7B is simplified for illustrative purposes, and thus, can be implemented as any of various other configurations while remaining within the scope of the present disclosure.

In some embodiments, the additional cells 625 can be configured to provide a sign bit. For example, for a selected cell 710 of the additional cells 625 can include a first logic state (e.g., “1”). The additional cells 625 and the memory cells 125 can be configured such that based on the sign bit, the data in the corresponding subset of the memory cells 125 is inverted (e.g., from “0” to “1”; from “1” to “0”) from the original data (e.g., “0” is shown in FIG. 7A for the corresponding cell 709). At a first column (BLB[0]), a first memory cell of the memory cells 125 can be inverted from “0” to “1,” at a second column (BLB[1]), a second memory cell of the memory cells 125 can be inverted from “1” to “0,” and at an M-th column (BLB[M−1]), an M-th memory cell of the memory cells 125 can be inverted from “0” to “1.” Without the additional cells 625 configured to provide the sign bit, the BL load, L^{m}, for an m-th BL is a function of a number of vias on the BLB,

$${L}^{m} = {\sum }_{i = 0}^{M - 1} ( {v}^{i} + 1 ) / 2.$$

Here, L^{m} can vary from 0 to N+1. With the additional cells 625 configured to provide the sign bit, the upper and lower limits for L^{m} can be limited such that the BL load variation is suppressed, as the mathematical limit of width in L^{m} in an N by M array with the sign column can be defined as

$${max}_{m} \{ {L}^{m} \} - {min}_{m} \{ {L}^{m} \} = Δ L ( N , M ) = N - 2 ⌊ {∅}_{N + 1}^{- 1} ( \frac{1}{2 M} ) ⌋ , \\ where {∅}_{N + 1}^{- 1}$$

is the inverse function of cumulative binomial distribution Ø_{N+1}(n). These inverted bits can be decoded in the sign decoder 650, which can provide an output identical to the original data.

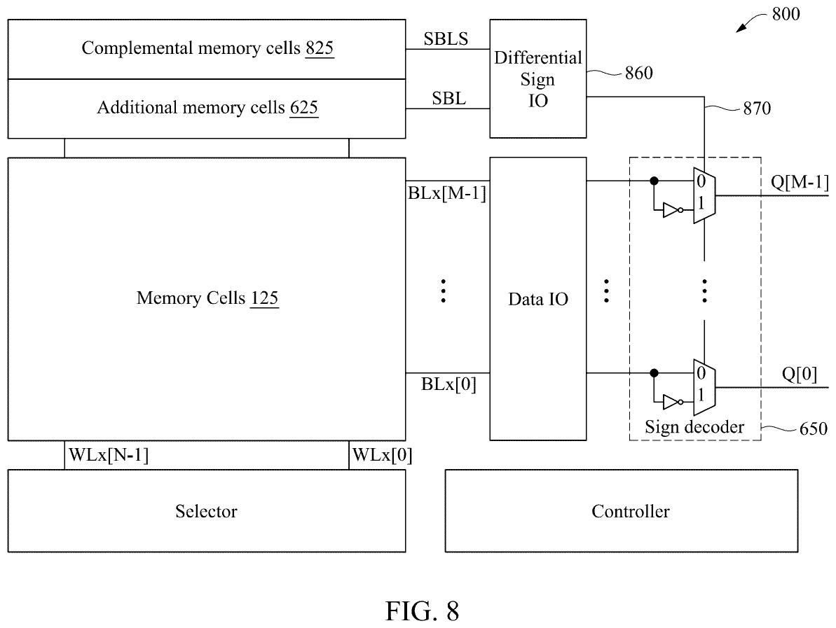

FIG. 8 illustrates a block diagram of an example memory device (or circuit) 800, in accordance with some embodiments. In some embodiments, the memory device 800 may be substantially similar to or incorporate features of the memory devices 100, 600, etc. The memory device 800 additionally includes complemental memory cells 825 and a differential sign I/O, as opposed to the memory device 600. It should be appreciated that the memory device 800 shown in FIG. 8 is simplified for illustrative purposes, and thus, can be implemented as any of various other configurations while remaining within the scope of the present disclosure. In some embodiments, the complemental memory cells 825 can extend along the second lateral direction. The complemental memory cells 825 and the differential sign I/O 860 can be configured such that a control signal 870 of the sign decoder 650 can reach earlier than the signals BLx.

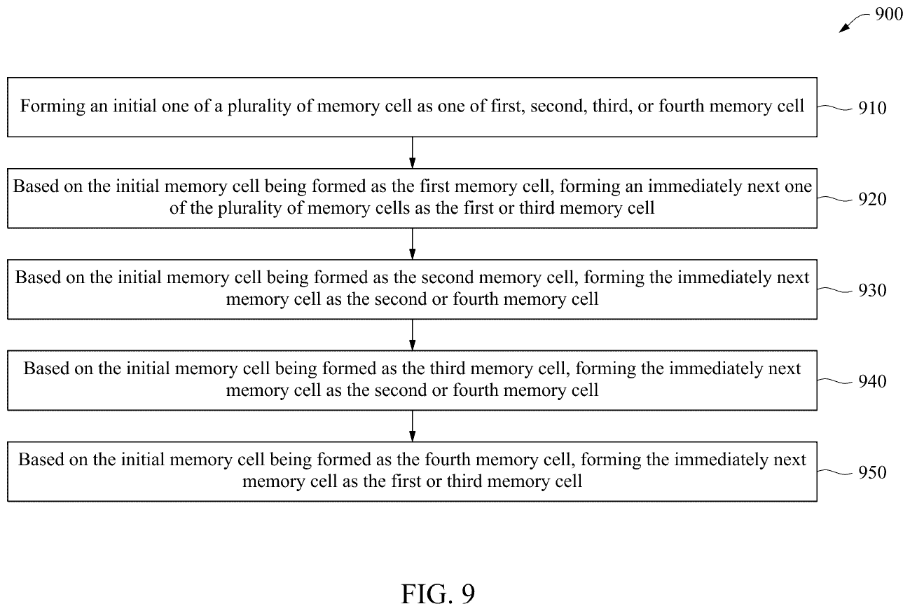

FIG. 9 is a flow chart of an example method 900 for programming a memory circuit, in accordance with some embodiments. The method 900 may be performed by one or more components of the circuits disclosed herein (e.g., the memory circuit 100, etc.). In some embodiments, the method 900 is performed by other entities. In some embodiments, the method 900 includes more, fewer, or different operations than shown in FIG. 9.

In a brief overview, the method 900 may begin with operation 910 of forming an initial one of a plurality of memory cell as one of first, second, third, or fourth memory cell. The method 900 may continue to operation 920 of based on the initial memory cell being formed as the first memory cell, forming an immediately next one of the plurality of memory cells as the first or third memory cell. The method 900 may continue to operation 930 of based on the initial memory cell being formed as the second memory cell, forming the immediately next memory cell as the second or fourth memory cell. The method 900 may continue to operation 940 of based on the initial memory cell being formed as the third memory cell, forming the immediately next memory cell as the second or fourth memory cell. The method 900 may continue to operation 950 of based on the initial memory cell being formed as the fourth memory cell, forming the immediately next memory cell as the first or third memory cell.

At operation 910, an initial one of a plurality of memory cell (e.g., the memory cell 125) is formed as one of first, second, third, or fourth memory cell (e.g., the memory cells 0A, 0B, 1A, 1B, as shown in FIG. 2). The first memory cell has its first and second source/drain terminals both connected to a reference line (e.g., the first interconnect structure 241). The second memory cell has its first and second source/drain terminals both connected to a signal line (e.g., the second interconnect structure 251, a bit line, a data line, etc.). The third memory cell has its first and second source/drain terminals connected to the signal line and the reference line, respectively. The fourth memory cell has its first and second source/drain terminals connected to the reference line and the signal line, respectively.

At operation 920, based on the initial memory cell being formed as the first memory cell, an immediately next one of the plurality of memory cells can be formed as the first or third memory cell. At operation 930, based on the initial memory cell being formed as the second memory cell, the immediately next memory cell can be formed as the second or fourth memory cell. At operation 940, based on the initial memory cell being formed as the third memory cell, the immediately next memory cell can be formed as the second or fourth memory cell. At operation 950, based on the initial memory cell being formed as the fourth memory cell, the immediately next memory cell can be formed as the first or third memory cell.

For example, as shown in FIG. 3, an initial cell (c0) can be formed as a fourth cell. With the fourth cell as an initial cell, an immediately next cell (c1) can be formed as a first cell (e.g., for d1=0). With the first cell 0A (c1) as an initial cell, a next cell (c2) can be formed as a first cell (e.g., for d2=0). With the first cell (c2) as an initial cell, a next cell (c3) can be formed as a third cell (e.g., for d3=1). With the third cell (c3) as an initial cell, a next cell (c4) can be formed as a fourth cell (e.g., for d4=1). With the fourth cell (c4) as an initial cell, a next cell (c5) can be formed as a third cell (e.g., for d5=1). With the third cell (c5) as an initial cell, a next cell (c6) can be formed as a second cell (e.g., for d6=0).

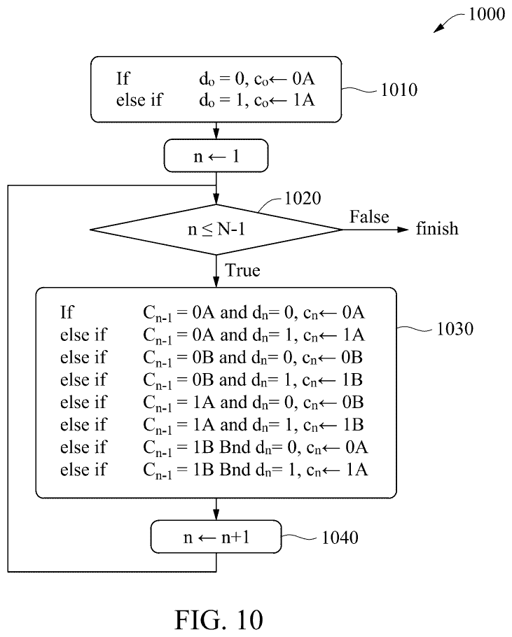

FIG. 10 is a flow chart of an example method 1000 for programming a memory circuit, in accordance with some embodiments. The method 1000 may be performed by one or more components of the circuits disclosed herein (e.g., the memory circuit 100, etc.). In some embodiments, the method 1000 is performed by other entities. In some embodiments, the method 900 includes more, fewer, or different operations than shown in FIG. 10.

In some embodiments, the method 1000 can be performed to embed original data, d^{m}=[d₀, . . . , d_{N-1}] (dᵢ∈{1, 0}), into memory cells, c^{m}=[c₀, . . . , c_{N-1}] (cᵢ∈{1A, 1B, 0A, 0B}), (e.g., of the memory arrays 220, 420, etc.). At operation 1010, in response to d₀ being “0,” an initial memory cell c₀ can be formed as a first memory cell (e.g., the memory cell 0A of FIG. 2). In response to d₀ being “1,” the initial memory cell c₀ can be formed as a third memory cell (e.g., the memory cell 1A of FIG. 2). At operation 1020, the method 1000 can continue to operation 1030 in response to the current number n being smaller than or equal to N−1. At operation 1020, in response to n being larger than N−1 (e.g., all the original data is embedded), the method 1000 can end. At operation 1030, an n-th memory cell (cₙ) can be formed as one of first, second, third, or fourth memory cell, based on the n-th data (dₙ) and the previous memory cell (cₙ₋₁).

In response to cₙ₋₁ being 0A and dₙ being “0,” cₙ can be formed as a first memory cell (0A). In response to cₙ₋₁ being 0A and dₙ being “1,” cₙ can be formed as a third memory cell (1A). In response to cₙ₋₁ being 0B and dₙ being “0,” cₙ can be formed as a second memory cell (0B). In response to cₙ₋₁ being 0B and dₙ being “1,” cₙ can be formed as a fourth memory cell (1B). In response to cₙ₋₁ being 1A and dₙ being “0,” cₙ can be formed as a second memory cell (0B). In response to cₙ₋₁ being 1A and dₙ being “1,” cₙ can be formed as a fourth memory cell (1B). In response to cₙ₋₁ being 1B and dₙ being “0,” cₙ can be formed as a first memory cell (0A). In response to cₙ₋₁ being 1B and dₙ being “1,” cₙ can be formed as a third memory cell (1A).

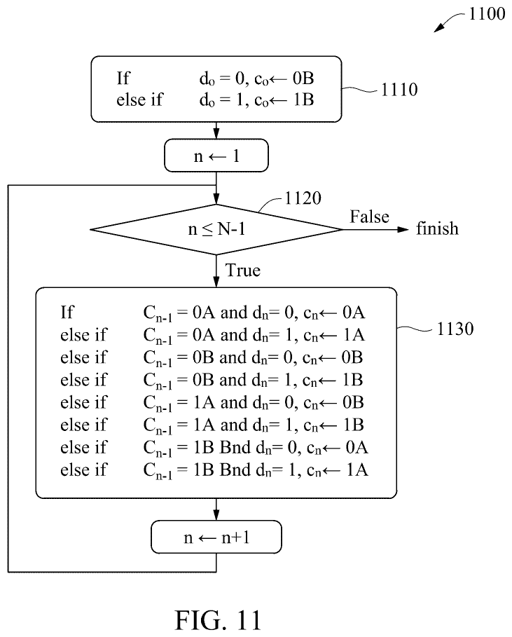

FIG. 11 is a flow chart of an example method 1100 for programming a memory circuit, in accordance with some embodiments. The method 1100 may be performed by one or more components of the circuits disclosed herein (e.g., the memory circuit 100, etc.). In some embodiments, the method 1100 is performed by other entities. In some embodiments, the method 900 includes more, fewer, or different operations than shown in FIG. 11.

In some embodiments, the method 1100 can be performed to embed original data, d^{m}=[d₀, . . . , d_{N-1}] (dᵢ∈{1, 0}), into memory cells, c^{m}=[c₀, . . . , c_{N-1}] (cᵢ∈{1A, 1B, 0A, 0B}), (e.g., of the memory arrays 220, 420, etc.). At operation 1110, in response to d₀ being “0,” an initial memory cell c₀ can be formed as a second memory cell (e.g., the memory cell 0B of FIG. 2). In response to d₀ being “1,” the initial memory cell c₀ can be formed as a fourth memory cell (e.g., the memory cell 1B of FIG. 2). At operation 1120, the method 1100 can continue to operation 1130 in response to the current number n being smaller than or equal to N−1. At operation 1120, in response to n being larger than N−1 (e.g., all the original data is embedded), the method 1100 can end. At operation 1130, an n-th memory cell (cₙ) can be formed as one of first, second, third, or fourth memory cell, based on the n-th data (dₙ) and the previous memory cell (cₙ₋₁).

In response to cₙ₋₁ being 0A and dₙ being “0,” cₙ can be formed as a first memory cell (0A). In response to cₙ₋₁ being 0A and dₙ being “1,” cₙ can be formed as a third memory cell (1A). In response to cₙ₋₁ being 0B and dₙ being “0,” cₙ can be formed as a second memory cell (0B). In response to cₙ₋₁ being 0B and dₙ being “1,” cₙ can be formed as a fourth memory cell (1B). In response to cₙ₋₁ being 1A and dₙ being “0,” cₙ can be formed as a second memory cell (0B). In response to cₙ₋₁ being 1A and dₙ being “1,” cₙ can be formed as a fourth memory cell (1B). In response to cₙ₋₁ being 1B and dₙ being “0,” cₙ can be formed as a first memory cell (0A). In response to cₙ₋₁ being 1B and dₙ being “1,” cₙ can be formed as a third memory cell (1A).

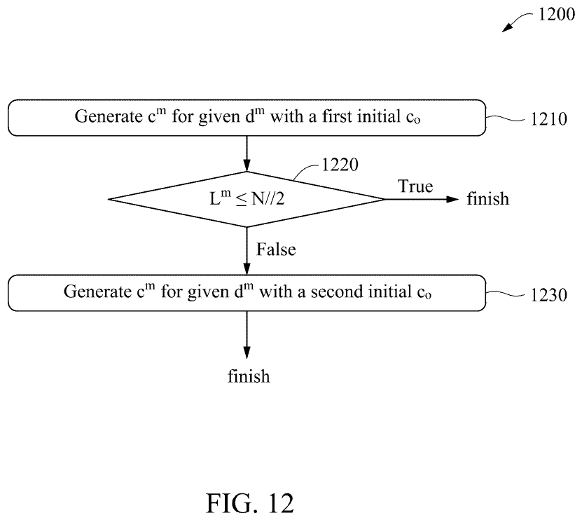

FIG. 12 is a flow chart of an example method 1200 for programming a memory circuit, in accordance with some embodiments. The method 1200 may be performed by one or more components of the circuits disclosed herein (e.g., the memory circuit 100, etc.). In some embodiments, the method 1200 is performed by other entities. In some embodiments, the method 900 includes more, fewer, or different operations than shown in FIG. 12.

At operation 1210, c^{m} can be generated for give original data d^{m} with a first initial cell Co. The first initial cell c₀ may be formed as a first memory cell (e.g., the first memory cell 0A) or a third memory cell (e.g., the third memory cell 1A). In some embodiments, the method 1200, at operation 1210, can perform the method 1000 to generate c^{m}. For example, the initial cell c₀ can be formed as a first memory cell (e.g., the first memory cell 0A) or a third memory cell (e.g., the third memory cell 1A), and then generate c^{m} based on operation 1020 to operation 1040.

At operation 1220, the BL load, L^{m}, can be calculated and compared with N//2 (as used herein, “//” is used as a floor division operator). In response to being L^{m} being smaller than or equal to N//2, the method 1200 may end at operation 1220. In response to being L^{m} being larger than N//2, the method 1200 may continue to operation 1230. At operation 1230, c^{m} can be generated for the give original data d^{m} with a second initial cell c₀. The second initial cell c₀ may be formed as a second memory cell (e.g., the second memory cell 1B) or a fourth memory cell (e.g., the fourth memory cell 1B). In some embodiments, the method 1200, at operation 1230, can perform the method 1100 to generate c^{m}. For example, the initial cell c₀ can be formed as a second memory cell (e.g., the second memory cell 0B) or a fourth memory cell (e.g., the fourth memory cell 1B), and then generate c^{m} based on operation 1120 to operation 1140.

In some embodiments, the method 1200, at operation 1210, can perform the method 1100 to generate c^{m}. For example, the initial cell c₀ can be formed as a second memory cell (e.g., the second memory cell 0B) or a fourth memory cell (e.g., the fourth memory cell 1B), and then generate c^{m} based on operation 1120 to operation 1140. The method 1200, at operation 1230, can perform the method 1000 to generate c^{m}. For example, the initial cell c₀ can be formed as a first memory cell (e.g., the first memory cell 0A) or a third memory cell (e.g., the third memory cell 1A), and then generate c^{m} based on operation 1020 to operation 1040.

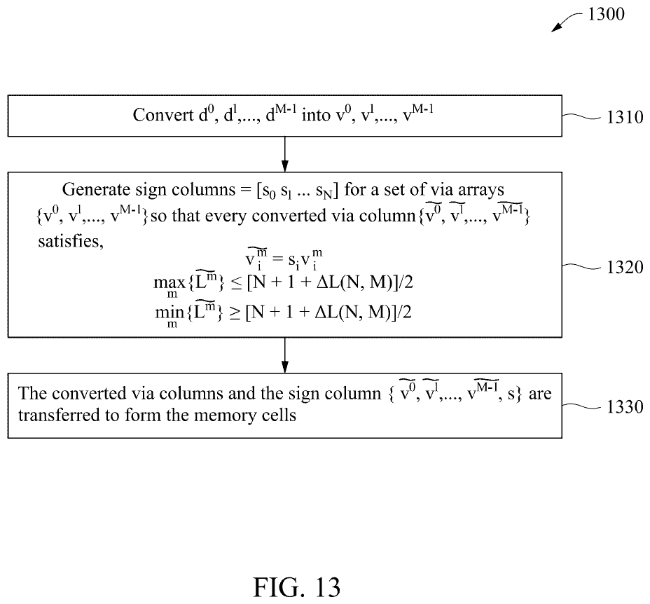

FIG. 13 is a flow chart of an example method 1300 for programming a memory circuit, in accordance with some embodiments. The method 1300 may be performed by one or more components of the circuits disclosed herein (e.g., the memory circuit 100, etc.). In some embodiments, the method 1300 is performed by other entities. In some embodiments, the method 1300 includes more, fewer, or different operations than shown in FIG. 13.

At operation 1310, the original data, d⁰, d¹, . . . , d^{M-1} can be converted into v⁰, v¹, . . . , v^{M-1}. In some embodiments, at operation 1310, the method 1300 can perform either of the method 1000, 1100, 1200, etc. to covert the original data, d⁰, d¹, . . . , d^{M-1} into v⁰, v¹, . . . , v^{M-1}.

At operation 1320, a sign column, s=[s₀, s₁, . . . , s_{N}], can be generated, based on the set of via arrays {v⁰, v¹, . . . , v^{M-1}}. The sign column can be generated such that a converted via column { [symbol] , [symbol] , . . . , [symbol] } satisfies

$$\text{?} = {s}_{i} {v}_{i}^{m} , where {v}_{i}^{m}$$

is vᵢ in v^{m}. Here, the associated load can be calculated as:

$${max}_{m} \{ \text{?} \} \leq [ N + 1 + Δ L ( N , M ) ] / 2 ; {min}_{m} \{ \text{?} \} \geq [ N + 1 - Δ L ( N , M ) ] / 2.$$

In some embodiments, at operation 1320, the converted via column can be inverted based on the load. For example, in response to [symbol] being larger than (N+1)/2, the via column, [symbol] , can be inverted to − [symbol] . This allows the distribution of BL load, [symbol] , to be between [N+1−ΔL(N, M)]/2 and (N+1)/2.

At operation 1330, the converted via columns and sign column, { [symbol] , [symbol] , . . . , [symbol] , s}, can be transferred to form the memory cells with the sign column (e.g., as shown in FIG. 7B).

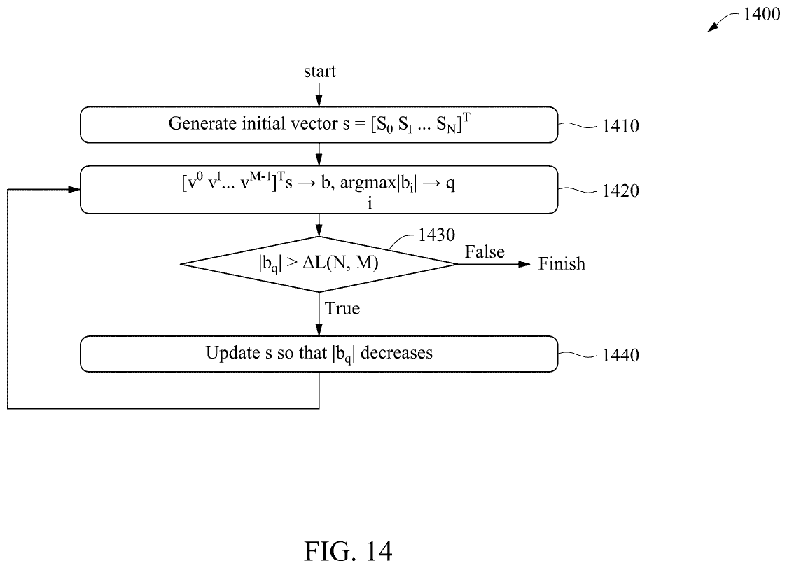

As discussed further below (e.g., with respect to FIG. 14 to FIG. 16), in some embodiments, the method 1300 can include performing various operations at operation 1320. FIG. 14 is a flow chart of an example method 1400 that can be performed as part of operation 1320 of the method 1300, in accordance with some embodiments. In some embodiments, the method 1400 can be performed to find an optimal vector for the sign column s. The method 1400 may be performed by one or more components of the circuits disclosed herein (e.g., the memory circuit 100, etc.). In some embodiments, the method 1400 is performed by other entities. In some embodiments, the method 1400 includes more, fewer, or different operations than shown in FIG. 14.

At operation 1410, an initial sign vector, s=[s₀, s₁, . . . , s_{N}]^{T}, for a sign column can be generated. As a simplified example, based on a via column,

$${[ {v}^{0} , {v}^{1} ]}^{T} = [ \begin{matrix}1 & 1 \\ 1 & 1\end{matrix} ] ,$$

an initial vector,

$$s = [ \begin{matrix}1 \\ 1\end{matrix} ]$$

can be generated. At operation 1420, a vector, b, for a number of vias on a bit line can be generated based on the via column and the initial sign vector. In the simplified example, the vector, b, can be generated as

$$b = [ \begin{matrix}2 \\ 2\end{matrix} ]$$

based on the example via column [v⁰, v¹]^{T} and the initial vector,

$$s = [ \begin{matrix}1 \\ 1\end{matrix} ] .$$

With the vector, b, an index of a column, q, can be found based on #argmaxᵢ|bᵢ|→q. In the simplified example, the index q may be found as 1 or 2. At operation 1430, in response to |b_{q}| being smaller than or equal to ΔL(N, M), the method 1400 may end and update the sign column. In some embodiments, the method 1400, at operation 1430, may continue to operation 1330 of the method 1300. At operation 1430, in response to |b_{q}| being larger than ΔL(N, M), the method 1400 may continue to operation 1440. At operation 1440, the sign column, s, can be updated such that |b_{q}| decreases and then continue to operation 1420. The method 1400 continue operations 1420 to 1440 until |b_{q}| is found smaller than or equal to ΔL(N, M).

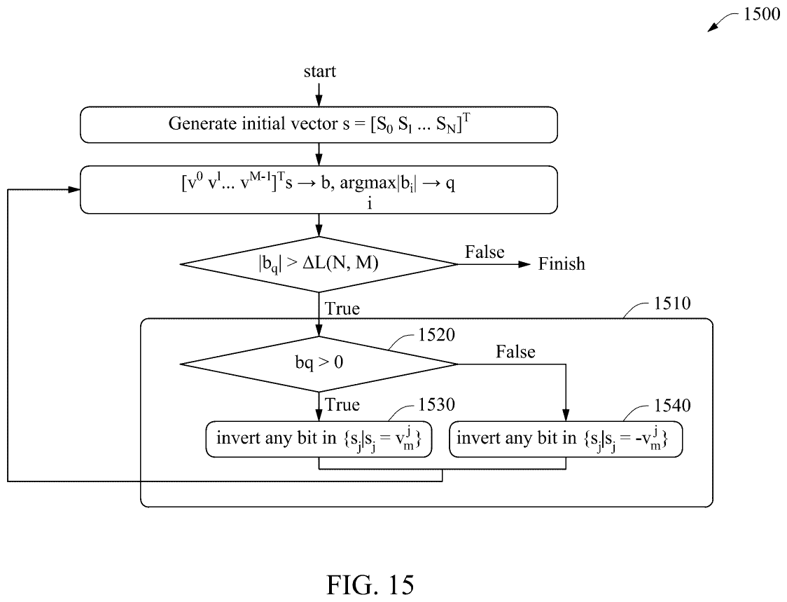

FIG. 15 is a flow chart of an example method 1500 that can be performed as part of operation 1320 of the method 1300, in accordance with some embodiments. In some embodiments, the method 1500 may be substantially similar to or incorporate features of the method 1400. For example, operation 1510 can be performed, at operation 1440, to update the sign column, s. In some embodiments, the method 1500 is performed by other entities. In some embodiments, the method 1500 includes more, fewer, or different operations than shown in FIG. 15.

At operation 1510, in updating the sign column, s, the method 1500 may include inverting a bit based on b_{q}. At operation 1520, the method 1500 includes determining whether b_{q} is larger than 0. In response to b_{q} being larger than 0, the method 1500 may continue to operation 1530, in which any bit that satisfies

$$\{ {s}_{j} \vert {s}_{j} = {v}_{m}^{j} \}$$

is inverted. In response to b_{q} being smaller than or equal to 0, the method 1500 may continue to operation 1540, in which any bit that satisfies

$$\{ {s}_{j} \vert {s}_{j} = - {v}_{m}^{j} \}$$

is inverted. In some embodiments, the method 1500 may end at operation 1510, and then may continue to operation 1420 of the method 1400.

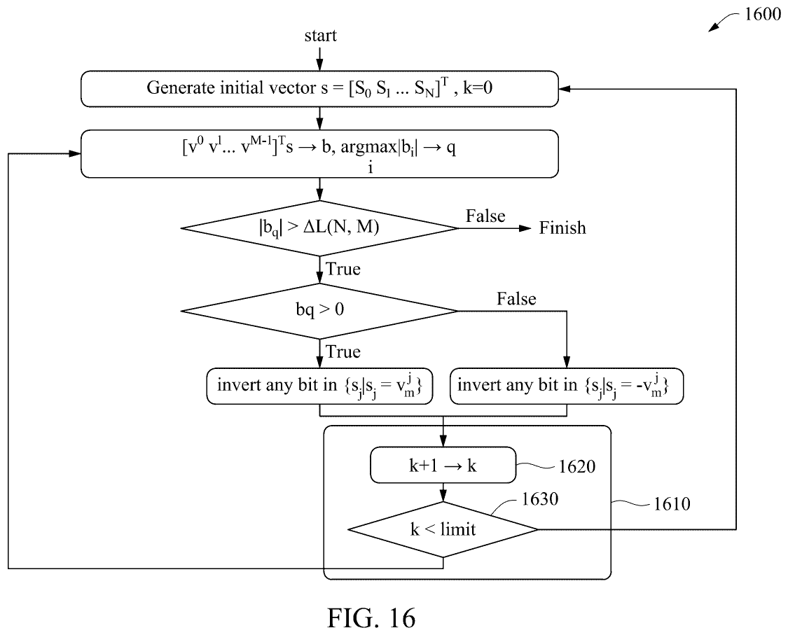

FIG. 16 is a flow chart of an example method 1600 that can be performed as part of operation 1320 of the method 1300, in accordance with some embodiments. In some embodiments, the method 1600 may be substantially similar to or incorporate features of the method 1500. For example, operation 1610 can be performed, in response to operation 1510, to update the sign column, s. In some embodiments, the method 1600 is performed by other entities. In some embodiments, the method 1600 includes more, fewer, or different operations than shown in FIG. 16.

In some embodiments, at operation 1620, in response to performing operation 1510 of the method 1500, the method 1600 may continue to operation 1610. With a variable k assigned to the initial vector, s, at operation 1620, the variable k can be increased by 1 for each updating operation. At operation 1630, the method 1600 includes determining whether the variable k is smaller than a predetermined limit. In response to k being smaller than the predetermined limit, the method 1600 may continue to operation 1420 of the method 1400. In response to k being larger than or equal to the predetermined limit, the method 1600 may continue to operation 1410 of the method 1400. With the iteration of the variable k, the method 1600 can prevent the updating operation from being trapped at a local minimum.

In one aspect of the present disclosure, a memory circuit is disclosed. The memory circuit includes a memory array including a plurality of memory cells. Each of the memory cells is selected from one of a first memory cell, a second memory cell, a third memory cell, or a fourth memory cell. The first memory cell includes a first transistor having a gate terminal coupled to a first word line, a first source/drain terminal coupled to a first interconnect structure carrying a ground voltage, and a second source/drain terminal coupled to the first interconnect structure. The second memory cell includes a second transistor having a gate terminal coupled to a second word line, a first source/drain terminal coupled to a second interconnect structure configured as a bit line, and a second source/drain terminal coupled to the second interconnect structure. The third memory cell includes a third transistor having a gate terminal coupled to a third word line, a first source/drain terminal coupled to the first interconnect structure, and a second source/drain terminal coupled to the second interconnect structure. The fourth memory cell includes a fourth transistor having a gate terminal coupled to a fourth word line, a first source/drain terminal coupled to the second interconnect structure, and a second source/drain terminal coupled to the first interconnect structure.

In another aspect of the present disclosure, a memory circuit is disclosed. The memory circuit includes a memory array including a plurality of memory cells arranged over a plurality of word lines extending along a first lateral direction, a plurality of reference lines extending along a second lateral direction perpendicular to the first lateral direction, and a plurality of signal lines extending along the second lateral direction. Each of the memory cells is selected from one of a first memory cell, a second memory cell, a third memory cell, or a fourth memory cell. The first memory cell includes its first and second source/drain terminals both connected to a corresponding one of the plurality of reference lines. The second memory cell includes its first and second source/drain terminals both connected to a corresponding one of the plurality of signal lines. The third memory cell includes its first and second source/drain terminals connected to a corresponding one of the plurality of signal lines and a corresponding one of the plurality of reference lines, respectively. The fourth memory cell includes its first and second source/drain terminals connected to a corresponding one of the plurality of reference lines and a corresponding one of the plurality of signal lines, respectively.

In yet another aspect of the present disclosure, a method for programming a memory circuit. The method includes forming an initial one of a plurality of memory cell as one of first, second, third, or fourth memory cell, wherein the first memory cell has its first and second source/drain terminals both connected to a reference line, the second memory cell has its first and second source/drain terminals both connected to a signal line, the third memory cell has its first and second source/drain terminals connected to the signal line and the reference line, respectively, the fourth memory cell has its first and second source/drain terminals connected to the reference line and the signal line, respectively, based on the initial memory cell being formed as the first memory cell, forming an immediately next one of the plurality of memory cells as the first or third memory cell, based on the initial memory cell being formed as the second memory cell, forming the immediately next memory cell as the second or fourth memory cell, based on the initial memory cell being formed as the third memory cell, forming the immediately next memory cell as the second or fourth memory cell, and based on the initial memory cell being formed as the fourth memory cell, forming the immediately next memory cell as the first or third memory cell.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory circuit, comprising:
a memory array comprising a plurality of memory cells;
wherein each of the memory cells is selected from one of a first memory cell, a second memory cell, a third memory cell, or a fourth memory cell;
wherein the first memory cell includes a first transistor having a gate terminal coupled to a first word line, a first source/drain terminal coupled to a first interconnect structure carrying a ground voltage, and a second source/drain terminal coupled to the first interconnect structure;
wherein the second memory cell includes a second transistor having a gate terminal coupled to a second word line, a first source/drain terminal coupled to a second interconnect structure configured as a bit line, and a second source/drain terminal coupled to the second interconnect structure;
wherein the third memory cell includes a third transistor having a gate terminal coupled to a third word line, a first source/drain terminal coupled to the first interconnect structure, and a second source/drain terminal coupled to the second interconnect structure; and
wherein the fourth memory cell includes a fourth transistor having a gate terminal coupled to a fourth word line, a first source/drain terminal coupled to the second interconnect structure, and a second source/drain terminal coupled to the first interconnect structure.

2. The memory circuit of claim 1, wherein each of the plurality of memory cells includes a read only memory (ROM) cell.

3. The memory circuit of claim 1, wherein the first and second memory cells operatively correspond to a first logic state, and the third and fourth memory cells operatively correspond to a second logic state.

4. The memory circuit of claim 1, wherein the first to fourth word lines physically extend in a first lateral direction, and the first and second interconnect structures extend in a second lateral direction perpendicular to the first lateral direction.

5. The memory circuit of claim 1, further comprising:
a pair of first via structures connecting the first and second source/drain terminals of the first transistor to the first interconnect structure;
a pair of second via structures connecting the first and second source/drain terminals of the second transistor to the second interconnect structure;
a pair of third via structures connecting the first and second source/drain terminals of the third transistor to the first interconnect structure and the second interconnect structure, respectively; and
a pair of fourth via structures connecting the first and second source/drain terminals of the fourth transistor to the second interconnect structure and the first interconnect structure, respectively.

6. The memory circuit of claim 5, wherein a number of the plurality of memory cells is equal to N, and a number of the first via structures or a number of the second via structures is equal to or less than N/2.

7. The memory circuit of claim 1, wherein the plurality of memory cells are physically arranged along a lateral direction, with an initial one of the plurality of memory cells being the first memory cell and an immediately next one of the plurality of memory cells being the first or third memory cell.

8. The memory circuit of claim 1, wherein the plurality of memory cells are physically arranged along a lateral direction, with an initial one of the plurality of memory cells being the second memory cell and an immediately next one of the plurality of memory cells being the second or fourth memory cell.

9. The memory circuit of claim 1, wherein the plurality of memory cells are physically arranged along a lateral direction, with an initial one of the plurality of memory cells being the third memory cell and an immediately next one of the plurality of memory cells being the second or fourth memory cell.

10. The memory circuit of claim 1, wherein the plurality of memory cells are physically arranged along a lateral direction, with an initial one of the plurality of memory cells being the fourth memory cell and an immediately next one of the plurality of memory cells being the first or third memory cell.

11. A memory circuit, comprising:
a memory array comprising a plurality of memory cells arranged over a plurality of word lines extending along a first lateral direction, a plurality of reference lines extending along a second lateral direction perpendicular to the first lateral direction, and a plurality of signal lines extending along the second lateral direction;
wherein each of the memory cells is selected from one of a first memory cell, a second memory cell, a third memory cell, or a fourth memory cell;
wherein the first memory cell having its first and second source/drain terminals both connected to a corresponding one of the plurality of reference lines;
wherein the second memory cell having its first and second source/drain terminals both connected to a corresponding one of the plurality of signal lines;
wherein the third memory cell having its first and second source/drain terminals connected to a corresponding one of the plurality of signal lines and a corresponding one of the plurality of reference lines, respectively; and
wherein the fourth memory cell having its first and second source/drain terminals connected to a corresponding one of the plurality of reference lines and a corresponding one of the plurality of signal lines, respectively.

12. The memory circuit of claim 11, wherein each subset of the plurality of memory cells extending along the second lateral direction are physically arranged, with an initial one of the plurality of memory cells being the first memory cell and an immediately next one of the plurality of memory cells being the first or third memory cell.

13. The memory circuit of claim 11, wherein each subset of the plurality of memory cells extending along the second lateral direction are physically arranged, with an initial one of the plurality of memory cells being the second memory cell and an immediately next one of the plurality of memory cells being the second or fourth memory cell.

14. The memory circuit of claim 11, wherein each subset of the plurality of memory cells extending along the second lateral direction are physically arranged, with an initial one of the plurality of memory cells being the third memory cell and an immediately next one of the plurality of memory cells being the second or fourth memory cell.

15. The memory circuit of claim 11, wherein each subset of the plurality of memory cells extending along the second lateral direction are physically arranged, with an initial one of the plurality of memory cells being the fourth memory cell and an immediately next one of the plurality of memory cells being the first or third memory cell.

16. The memory circuit of claim 11, wherein the memory further comprises a plurality of additional memory cells extending along the second lateral direction, and wherein each of the plurality of additional memory cells operatively corresponds to a sign of a corresponding subset of the plurality of memory cells arranged along the first lateral direction.

17. The memory circuit of claim 11, wherein the first and second memory cells operatively correspond to a first logic state, and the third and fourth memory cells operatively correspond to a second logic state.

18. A method for programming a memory circuit, comprising:
forming an initial one of a plurality of memory cell as one of first, second, third, or fourth memory cell, wherein the first memory cell has its first and second source/drain terminals both connected to a reference line, the second memory cell has its first and second source/drain terminals both connected to a signal line, the third memory cell has its first and second source/drain terminals connected to the signal line and the reference line, respectively, the fourth memory cell has its first and second source/drain terminals connected to the reference line and the signal line, respectively;
based on the initial memory cell being formed as the first memory cell, forming an immediately next one of the plurality of memory cells as the first or third memory cell;
based on the initial memory cell being formed as the second memory cell, forming the immediately next memory cell as the second or fourth memory cell;
based on the initial memory cell being formed as the third memory cell, forming the immediately next memory cell as the second or fourth memory cell; and
based on the initial memory cell being formed as the fourth memory cell, forming the immediately next memory cell as the first or third memory cell.

19. The method of claim 18, wherein each of the plurality of memory cells includes a read only memory (ROM) cell.

20. The method of claim 18, wherein the plurality of memory cells are arranged along a lateral direction.
